(19) United States
(12) Patent Application Publication
(10) Pub. No.: US 2003/0020397 A1
(43) Pub. Date: Jan. 30, 2003

(54) Enhancement of luminance and life in electroluminescent devices

(75) Inventor: Paul Hanlon James Beatty, Novato, CA (US)

Correspondence Address: MICHAEL BEST & FRIEDRICH, LLP, 100 E WISCONSIN AVENUE, MILWAUKEE, WI, 53202, US

(73) Assignee: Lite Array Inc., Novato, CA (US)

(21) Appl. No.: 10/185,749

(22) Filed: Jun. 28, 2002

Related U.S. Application Data
(60) Provisional application No. 60/301,995, filed on Jun. 28, 2001.

(51) Int. Cl. H05B 33/22

(52) U.S. Cl. 313/503

(57) ABSTRACT

An electroluminescent device including a first electrode layer, a second electrode layer, and a light-emitting layer disposed between the first and second electrode layers. The light-emitting layer includes a polycrystalline or amorphous material from which light can be trapped by total internal reflection until reaching a region of crystallite size capable of scattering light.

### RELATED APPLICATIONS

This patent application claims the benefit of U.S. Provisional Patent Application No. 60/301,995, entitled “ENHANCEMENT OF LUMINANCE AND LIFE IN ELECTROLUMINESCENCE,” filed on Jun. 28, 2001, the entire content of which is incorporated herein by reference.

### BACKGROUND OF THE INVENTION

The present invention relates to electroluminescent (“EL”) devices and more specifically, to thin film electroluminescent (“TFEL”) displays.

EL devices use a single film or multiple films that emit light to illuminate the panel and depict images and/or text to a user. The films, typically of a phosphor material or organic material doped with light-emitting molecules, are capable of emitting light when a voltage is applied across the thickness of the film. The light-emitting layer is sandwiched between a first layer of electrodes (thin strips with conductive properties) and a second layer of electrodes orthogonal to the first layer. For example, the first layer consists of column electrodes which extend from the top of the panel to the bottom. The second layer consists of row electrodes which extend from the left side of the panel to the right side. The areas on the panel where the various row and column electrodes overlap form pixels. When the row and column electrodes establish the required potential difference, the corresponding pixels will emit light and the panel will illuminate.

### SUMMARY OF THE INVENTION

However, most of the light emitted from the light-emitting layer becomes trapped by total internal reflection (“TIR”). The high refractive index of the light-emitting film and the low refractive indices of adjacent films cause TIR. Depending on these refractive indices, approximately up to 90% of the emitted light is trapped within the panel. As shown in FIG. 1, for example, a light-emitting film 10 of zinc sulfide doped with manganese (“ZnS:Mn”) is positioned between two dielectric layers 12 and 14 of silicon oxynitride (“SiON”). The light-emitting film 10 has an index of refraction of approximately 2.3 to approximately 2.4. The dielectric layers 12 and 14 both have indices of refraction of approximately 1.75. Due to the large difference in the indices of refraction for the light-emitting layer 10 compared to the dielectric layer 12, the dielectric layer 12 reflects incident light 16 emitted from the manganese ions in the light-emitting film 10. Light 16 is then reflected again by the dielectric layer 14 and continues to be trapped by TIR. Some light emitted from the light-emitting layer 10 transmits through the dielectric layer 12. For example, when incident on the dielectric layer 12, light 18 emitted from the manganese ions in the light-emitting film 10 is not reflected by the layer 12. Rather, light 18 travels through the dielectric layer 12 and exits the layer 12 toward an observer.

Currently, TIR limits the efficiency and size of most EL devices. In order to increase the luminance of the device, the device applies a larger potential difference across the electrodes. This produces a larger power consumption for the device. Since a larger percentage of emitted light is trapped by TIR, an increase in power consumption causes the devices to be largely inefficient. Also, an increase in the potential difference across electrodes leads to non-uniformity of luminance. The non-uniformity is often caused by the breakdown within the light-emitting layer from the higher current flowing through the device. This limits the size of the devices so as to avoid non-uniformity of luminance. Raising the efficiency of EL devices would allow for larger devices and an increased luminance without an increase in power consumption.

In one embodiment, the invention provides an electroluminescent display including a first electrode layer, and second electrode layer, and a light-emitting layer disposed between the first and second electrode layers. The first electrode layer includes a plurality of row electrodes and the second electrode layer includes a plurality of column electrodes orthogonal to the row electrodes. The display also includes a plurality of pixels and a plurality of inter-pixel areas. The light-emitting layer includes a polycrystalline material reflecting light trapped by TIR and is located within the pixel. The light-emitting layer also has larger crystallites to scatter out the light in the inter-pixel area.

In another embodiment, the invention provides an electroluminescent device including first and second electrode layers and a light-emitting layer disposed between the first and second electrode layers. The first electrode layer includes a plurality of row electrodes and the second electrode layer includes a plurality of column electrodes orthogonal to the row electrodes. Both electrode layers are layers of a substantially non-transparent material, such as aluminum. The device also includes a plurality of pixels and a plurality of inter-pixel areas. The light-emitting layer includes at least one crystallite positioned in a inter-pixel area. Light emitted from the light-emitting layer reflects back and forth between the non-transparent electrode layers until the light reaches the crystallite which scatters and emits light through the inter-pixel area.

In still another embodiment, the invention provides a method of fabricating an electroluminescent device that emits light to an observer and has a plurality of layers. The method includes depositing the layers onto a viewing surface and thermally treating the layers such that they have larger crystallites which scatter and enhance the amount of light emitted to the observer. Laser annealing and ultra-violet exposure can be used to thermally treat the layers.

In a further embodiment, the invention provides an electroluminescent device having a plurality of layers deposited on a viewing surface. The device includes a light-emitting means and a light-scattering means for increasing a luminance of the device. The device also includes a conducting means for establishing a voltage across the light-emitting means.

Other features and advantages of the invention will become apparent by consideration of the detailed description and accompanying drawings.

### BRIEF DESCRIPTION OF THE DRAWINGS

FIG. 1 is a schematic diagram illustrating the trapping of emitted light within a light-emitting layer of a prior art EL device.

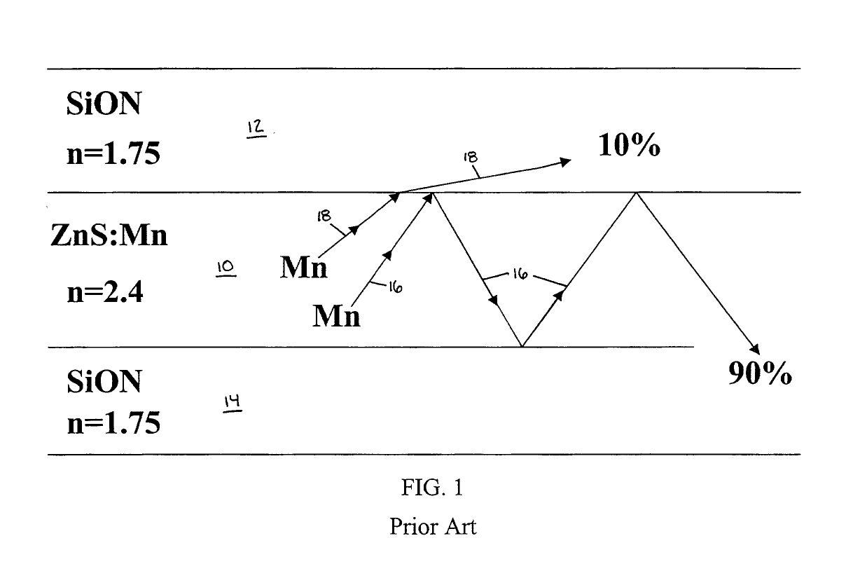

FIG. 2 is a schematic diagram of a film stack included in an inorganic EL display device embodying the invention.

FIG. 3 is a schematic diagram of a film stack included in an organic light-emitting diode (“OLED”) device embodying the invention.

FIG. 4 is a partial schematic diagram of either the EL or OLED display device shown in FIGS. 2 and 3.

FIG. 5 is a partial cross-sectional view of the device shown in FIG. 4 taken along line 5-5.

FIG. 6 is a partial schematic diagram the device shown in FIG. 4 being etched.

FIG. 7 illustrates the device shown in FIG. 5 in an alternative embodiment of the invention.

FIG. 8 is a schematic diagram of another embodiment of a light-emitting layer etched to emit TIR light.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

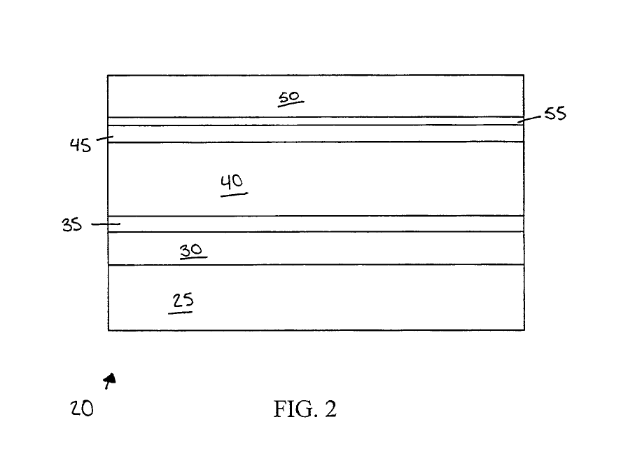

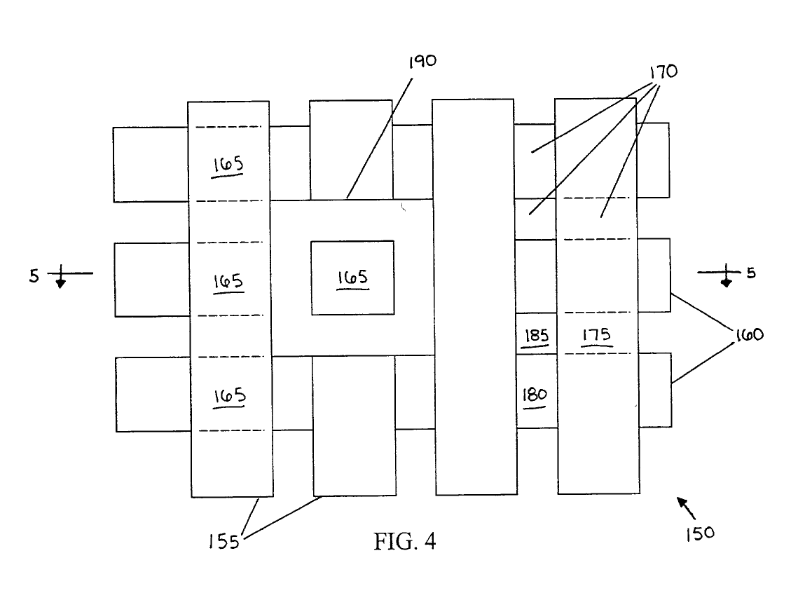

FIG. 2 illustrates a film stack 20 included in an inorganic TFEL device. The stack 20 includes a viewing surface 25 and a series of thin layers or films disposed on top of the viewing surface 25. In one embodiment, the viewing surface 25 is a glass layer approximately 0.7 nm to about 1.1 nm thick. A front electrode layer 30 is deposited onto the viewing surface 25. The front electrode layer 30 is etched and arranged into a plurality of parallel strips or electrodes 155 (see FIG. 4). The front electrode layer 30 is typically 1,200 Angstroms thick and is made from a substantially conductive material. In one embodiment, the front electrode layer 30 is made from indium tin oxide (“ITO”). In another embodiment, the front electrode layer 30 of ITO includes tiny strips of aluminum (“Al”) to reduce the resistivity and increase conductivity of the layer 30. In further embodiments, the front electrode layer 30 is made entirely from Al, chrome oxide on chromium (“CrO—Cr”), or another substantially conductive and non-transparent material.

A first dielectric layer 35 is disposed onto the front electrode layer 30. The first dielectric layer 35 is a layer of SiON and is approximately 2,100 Angstroms thick. In other embodiments, the dielectric layer is a layer of yttrium oxide (“Y₂O₃”) or silicon oxynitride (“SiAlON”). The film stack 20 also includes a light-emitting layer 40 that is disposed onto the first dielectric layer 35 or, in other embodiments, disposed onto the front electrode layer 30. The light-emitting layer 40 consists of a phosphor material (which in most embodiments is doped with ions) and is capable of emitting light when a specified voltage is applied across the layer 40. In one embodiment, the light-emitting layer 40 is a layer of polycrystalline material. In another embodiment, the light-emitting layer 40 is a layer of zinc sulfide doped with manganese (“ZnS:Mn”) and is approximately 5,800 Angstroms thick.

The film stack 20 further includes a second dielectric layer 45 disposed onto the light-emitting layer 40. The second dielectric layer 45 is approximately 1,800 Angstroms and, in the embodiment shown, consists of the same material as the first dielectric layer 35. In other embodiments, the first and second dielectric layers 35 and 45 may be made from different material such as SiON for layer 35 and Y₂O₃ or SiAlON for layer 45.

The last layer deposited is the counter electrode layer or rear electrode layer 50. In one embodiment, the rear electrode layer 50 is etched and arranged into a plurality of parallel strips or electrodes 160 (see FIG. 4), which are orthogonal to the electrodes 155 of the first electrode layer 30. The rear electrode layer 50 is a layer of Al approximately 1,500 Angstroms thick. In the embodiment shown, a light-absorbing layer 55 is positioned below the rear electrode layer 50. The light-absorbing layer 55 reduces the reflection of ambient light incident on the device. In other embodiments (not shown), the light-absorbing layer 55 may be eliminated from the film stack 20.

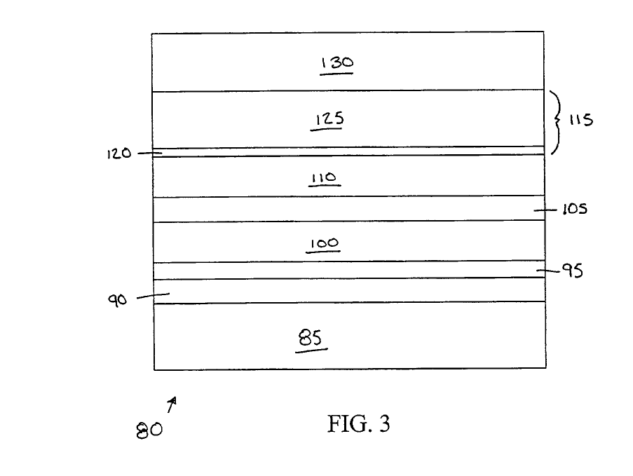

FIG. 3 illustrates a film stack 80 included in an OLED device. The stack 80 includes a series of thin films or layers disposed on a viewing surface 85 of glass, similar to the film stack 20 in the TFEL display panel. The first layer deposited onto the viewing surface 85 is a first electrode or anode layer 90. In one embodiment, the anode layer 90 is a thin layer of ITO and is etched and arranged into a plurality of parallel strips or electrodes 155, similar to the first electrode layer 30 of stack 20.

The stack 80 also includes a hole injection (“HI”) layer 95 deposited on the anode layer 90 and a hole transport (“HT”) layer 100 deposited on the HI layer 95. The HI layer 95 is a layer of copper phthalocyanine (“CuPc”) and acts as an anode buffer layer and facilitates hole injection. The HT layer 100 is a layer of N,N′-Bis(napthalen-1-yl)-N, N′-bis(phenyl)benzidine (“NPB”).

The film stack 80 further includes a light-emitting layer 105 of doped 8-hydroxyquinoline aluminum (“Alq”) and an electron transport (“ET”) layer 110 of undoped Alq. In one embodiment, the light-emitting layer 105 is doped with light-emitting molecules. The light-emitting layer 105 is deposited onto the HT layer 100, and the ET layer 110 is deposited onto the light-emitting layer 105.

The stack 80 also includes a second electrode or multilayer cathode layer 115. The cathode layer 115 includes a first thin layer 120 of lithium fluoride (“LiF”) and a second layer 125 of Al. The first thin layer 120 of LiF functions as an extremely thin interlayer below the aluminum layer 125 to avoid a reduction in efficiency from using aluminum, which has a higher work function. In other embodiments, the cathode layer 115 is etched and arranged into a plurality of parallel strips or electrodes 160 (see FIG. 4), which are orthogonal to the electrodes 155 of the anode layer 90. In other embodiments, the cathode layer 115 includes a single layer or multiple layers of magnesium-silver (“MgAg”) or other conductive materials with low work functions. In further embodiments, the stack 80 also includes a layer 130 of inert gas with desiccant deposited on the cathode layer 115.

FIG. 4 illustrates a partial schematic diagram of the display panel of an EL device 150. The EL device 150 is an inorganic TFEL display, an OLED device, or another electroluminescent device. The device 150 includes a plurality of front or column electrodes 155 and a plurality of rear or row electrodes 160. The remaining layers of the device, including the light-emitting layer, are positioned between the column electrodes 155 and the row electrodes 160, but are not shown for purposes of simplicity and clarity. As is commonly known in the art, each electrode is connected to a corresponding driver circuit (not shown) which supplies the power necessary for establishing the required potential difference across the light-emitting layer (not shown).

The column electrodes 155 and row electrodes 160 together define a plurality of pixels 165 and a plurality of inter-pixel areas 170. The pixels 165 are the area defined by a portion of a column electrode 155 overlapping a portion of a row electrode 160. The inter-pixel areas 170 are the areas void of any column electrode overlapping another row electrode. For example, inter-pixel area 175 is an area of a column electrode 155 that does not overlap a row electrode 160. Inter-pixel area 180 is an area of a row column 160 not overlapped by a column electrode 155 and inter-pixel area 185 is an area void of any column or row electrode whatsoever.

In one embodiment, the column electrodes 155 are ITO electrodes and the row electrodes 160 are Al electrodes. Forming the column electrodes 155 out of ITO allows the pixels 165 to be transparent and emit light. However, ITO electrodes have a higher resistivity than Al electrodes resulting in a larger power requirement. In another embodiment where both the column electrodes 155 and the row electrodes 160 are formed from Al, the power requirement is decreased compared to the panel having ITO electrodes. However, this causes the pixels 165 to be reflective to light and relies on the inter-pixels areas 170 to scatter light. This will be discussed in more detail below.

After the deposition of the layers in either film stack 20 or 80, the stack 20/80 undergoes heat treatment. With a sufficient amount of heat, the thermal treatment grows crystalline scattering states or crystallites of the phosphor or organic material in the light-emitting layer 40/105. In the preferred embodiment (not shown), the crystallites are positioned in the light-emitting layer 40/105 along the boundary of the pixels 165 and the inter-pixel areas 170. In other embodiments (not shown), the crystallites are positioned in the pixels 165, positioned in the inter-pixel areas 175, or positioned randomly throughout the light-emitting layer 40/104. Moderate thermal treatment thereby allows crystallites to grow increasing the emission of light due to a longer electron acceleration path, but not so large that the crystallites scatter ambient light. Crystallites beyond a size of about 0.4 microns scatter ambient illumination (light from a source other than the light-emitting layer) such that the contrast of the panel is degraded and the benefit of scattering TIR light is not available. In other embodiments, the crystallites grow in the other layers where scattering occurs rather than the light-emitting layer 40/105, such as the HI layer 95, the HT layer 100, or the ET layer 110.

For OLED devices, heat crystallizes the amorphous organic films and makes the light emission process less efficient. Therefore, the pixels 165 of OLED devices need to remain in an amorphous state, while the inter-pixel areas 170 are treated to grow crystallites.

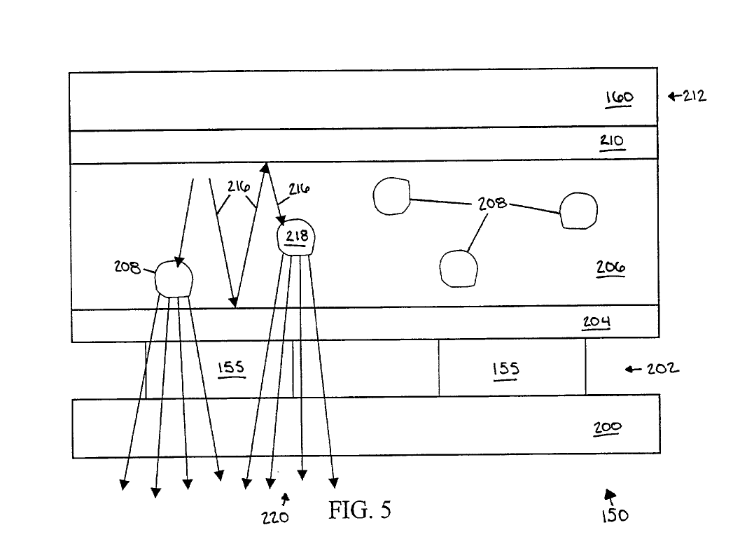

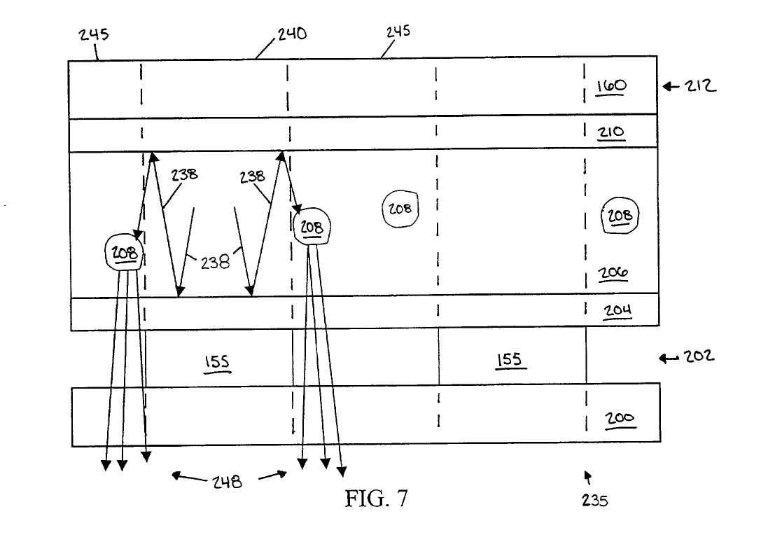

FIG. 5 illustrates the cross-section of the EL device 150 depicted in FIG. 4 and illustrates how crystalline growth within an EL device reduces TIR. The EL device 150 includes a viewing surface 200 and a front electrode layer 202 deposited on the viewing surface 200. In the embodiment shown, the front electrode layer 202 is a layer of ITO and includes the plurality of column electrodes 155. A first dielectric layer 204 is disposed on top of the front electrode layer 202 and a light-emitting layer 206 is disposed on top of the dielectric layer 204. The light-emitting layer 206 includes a plurality of crystallites 208. Only a few of the crystallites 208 are shown. Moreover, the crystallites are merely shown for the purpose of illustration. As such, FIGS. 5 and 7 do not reflect the actual size or number of the crystallites. In the preferred embodiment, the crystallites are roughly 0.4 microns or less in size. The device 150 further includes a second dielectric layer 210 deposited on the light-emitting layer 206 and a rear electrode layer 212 deposited on the second dielectric layer 210. In the embodiment shown, the rear electrode layer 212 is a layer of Al and includes the plurality of counter electrodes 160.

Still referring to FIG. 5, when the specified voltage is applied to the column electrodes 155 and the row electrodes 160, light 216 is emitted from the light-emitting layer 206. In some incidences, the light 216 emitted from the light-emitting layer 206 is reflected in the layer 206 by the first dielectric layer 204 and/or the second dielectric layer 210. Rather than becoming trapped by TIR, a crystallite 218 located within the light-emitting layer 206 scatters the light 216 when the beam 216 is incident on the crystallite 218. This produces more light 220 emitted from the device 150 and increases the luminance of the panel 150.

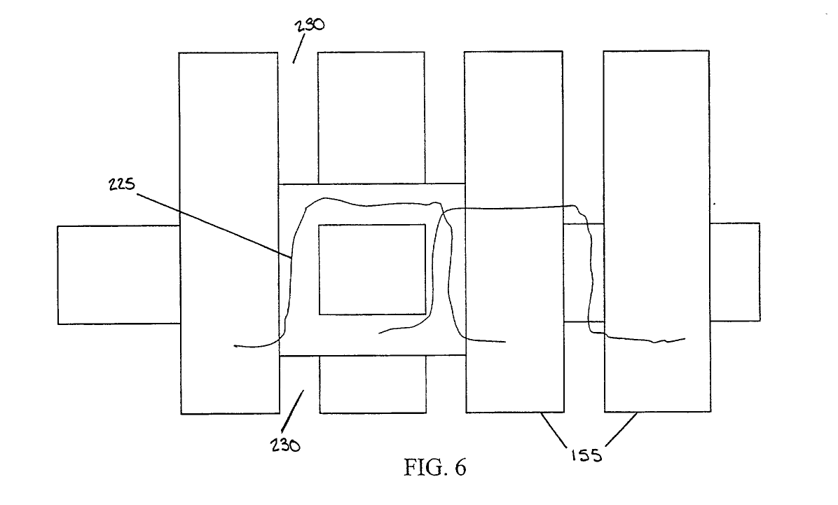

The thermal treatment process utilizes a laser beam having a beam width matching the dimension of a pixel 165 (see FIG. 4) plus the width of the adjacent inter-pixel areas 170 (see FIG. 4). The beam scans the column electrodes 155. While scanning down the column electrodes 155, the beams overlap only in the inter-pixel areas 170, creating larger crystallites that scatter the trapped emitted light towards an observer. This effect produces an enhanced pixel area 190 (only one of which is shown), which appears larger and brighter than the regular pixel area 165 as shown in FIG. 4. The thermal treatment can be accomplished as a by-product of laser annealing the pixels 165. In another embodiment, a laser beam with a smaller width, approximately the size of the inter-pixel areas 170 or smaller, is used to create crystallite growth as an alternative to the overlapping beams of the wider laser. As shown in FIG. 6, a laser beam 225 with a beam width of approximately 10 microns heats inter-pixel areas 230. The inter-pixel areas 230 are approximately 60 microns wide.

Crystallite growth in the inter-pixel areas 170 (see FIG. 4) also allows for non-transparent material to be used in the front or column electrodes 155. The crystallites within the inter-pixel areas 170 scatter TIR light to the observer and illuminate the panel. In one embodiment, a small laser beam having a beam width of the inter-pixel area 170 heats the inter-pixel areas 170 and creates crystallite growth within the areas 170. In another embodiment, a flood beam of ultra-violet (“UV”) light is used to cause crystallite growth. The UV excitation is absorbed only by the inter-pixel areas 170 and is reflected by the reflective column electrodes 155. The inter-pixel areas 170 are thus converted to the scattering states. This arrangement and method is particularly relevant to OLED devices where the pixels 165 must not be overheated.

For inorganic TFEL display panels using metal column electrodes 155, laser annealing can be done prior to the rear electrode layer deposition. The pixels 165 still receive the benefit of sufficient heating for the conversion to the more efficient crystalline state. After the rear electrode layer deposition, the inter-pixel areas 170 may receive a second exposure to increase the crystallite growth for scattering TIR light.

FIG. 7 illustrates an EL device 235 that is similar to the EL device 150 shown and described in FIG. 5. Similar elements in the EL devices 150 and 235 are described using the same reference numerals. The differences between the EL device 235 of FIG. 7 and the EL device 150 of FIG. 4 are 1) the column electrodes 155 of the EL device 235 are etched from a layer of Al rather than from a layer of ITO and 2) the crystallites 208 are mainly located within inter-pixel areas 245 (boundary defined by the dashed lines). Al electrodes are substantially non-transparent and causes the column electrodes 155 of the EL device 235 to reflect light. This causes the EL device 235 to emit light through the inter-pixel areas 245 rather than through pixels 240 (boundary defined by the dashed line).

In the case of metal row electrodes 160 and column electrodes 155 such as the embodiment shown in FIG. 7, the light 238 generated by the light-emitting layer 206 is contained within the pixels 240. Light 238 continues to be reflected between the electrodes 155 and 160 or between the dielectric layers 204 and 210 until it reaches the edges of the pixel area 240. At the edge of the pixel area 240, the light 238 is scattered by the crystallites 208 within the inter-pixel areas 245 and emits scattered light 248 from the device 235 through the inter-pixel areas 245.

In another embodiment (not shown), subpixelation is used to reduce TIR for large pixel areas where the TIR light might be absorbed on successive reflections in the layers. For example, in a device with large pixels of approximately 275 microns, the crystallites (not shown) are positioned within the light-emitting layer or another layer approximately every 15 microns forming the boundaries of subpixels. The crystallites then produce scattered light from the subpixels. In a further embodiment of subpixelation (not shown), gaps are etched into the light-emitting layer approximately every 15 microns. The gaps are etched into the light-emitting layer using photolithography, laser or reactive ion etching (“RIE”). Scattering of emitted light then comes from about one to about five micron wide gaps between the subpixels. In further embodiments (not shown), the gaps are etched into the other layers rather than the light-emitting layer 40/105, such as the HI layer 95, the HT layer 100, or the ET layer 110.

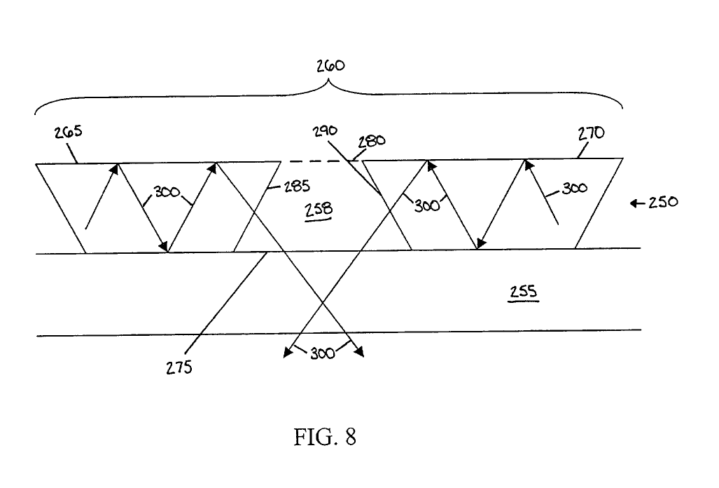

In the embodiment shown in FIG. 8, undercutting is used to form the gaps for subpixelation. A light-emitting film 250, such as ZnS:Mn or Alq, is deposited on a viewing surface 255. A gap 258 is etched into a pixel 260 in the light-emitting film 250 creating two subpixels 265 and 270. The gap 258 includes a base 275, a top 280 (represented by the dashed line), and two sloping sidewalls 285 and 290. The base 275 of the gap 258 is larger than the top 280 in order to produce the sloping sidewalls 285 and 290 at an angle which will not create additional TIR light. The sloping sidewalls 285 and 290 are positioned at an angle that will allow emitted light 300 to escape. In one embodiment, the light-emitting layer 250 is etched using wet photolithography.

In another embodiment (not shown), the front electrode layer 30/90 (which contains the plurality of column electrodes 155) is roughened, creating a “frosted” effect. The roughened surface of the column electrodes 155 also scatters light and increases the device's luminance. Laser annealing or mechanical scribing is used to roughen the surface of the column electrodes 155 without cutting through the electrodes 155. In other embodiments, other layers of the film stack 20/80 are roughened to increase light scattering.

Thus, the invention provides, among other things, an electroluminescent device having a light-emitting layer containing crystallites to scatter light and reduce the reflectance of the display. Various features and advantages of the invention are set forth in the following claims.

What is claimed is:

1. An electroluminescent device including a plurality of layers, the device comprising:
a first electrode layer;
a second electrode layer;
a light-emitting layer disposed between the first and second electrode layers; and
at least one crystallite formed in a layer.

2. The electroluminescent device as set forth in claim 1, wherein the first electrode layer includes a plurality of row electrodes and the second electrode layer includes a plurality of column electrodes.

3. The electroluminescent device as set forth in claim 2, further comprising:
a plurality of pixels, wherein the pixel is an area of the device where a row electrode overlaps a column electrode; and
a plurality of inter-pixel areas, wherein the inter-pixel area is an area of the device void of any electrode overlapping another electrode, and wherein the crystallite is positioned in one inter-pixel area.

4. The electroluminescent device as set forth in claim 1, wherein the crystallite is formed by heat treatment.

5. The electroluminescent device as set forth in claim 3, wherein the crystallite is formed by laser annealing.

6. The electroluminescent device as set forth in claim 3, wherein the crystallite is formed by ultra-violet exposure.

7. The electroluminescent device as set forth in claim 1, wherein the crystallite is formed by laser annealing.

8. The electroluminescent device as set forth in claim 1, wherein the crystallite is formed by ultra-violet exposure.

9. The electroluminescent device as set forth in claim 1, wherein one electrode layer includes a roughened surface.

10. The electroluminescent device as set forth in claim 9, wherein the roughened surface is formed by laser annealing.

11. The electroluminescent device as set forth in claim 3, wherein one electrode layer includes a roughened surface over inter-pixel areas.

12. The electroluminescent device as set forth in claim 11, wherein the roughened surface is formed by laser annealing.

13. The electroluminescent device as set forth in claim 1, wherein the crystallite has a size of approximately 0.4 microns.

14. The electroluminescent device as set forth in claim 1, further including a plurality of crystallites.

15. The electroluminescent device as set forth in claim 1, wherein the first electrode layer is formed from indium tin oxide, the second electrode layer is formed from aluminum, the light-emitting layer is formed from zinc sulfide doped with manganese, and the crystallite is located within the light-emitting layer.

16. The electroluminescent device as set forth in claim 3, wherein the first electrode layer is formed from indium tin oxide, the second electrode layer is formed from aluminum, the light-emitting layer is formed from zinc sulfide doped with manganese, and the crystallite is located within the light-emitting layer.

17. The electroluminescent device as set forth in claim 1, wherein the first electrode layer and the second electrode layer is formed from aluminum, the light-emitting layer is formed from zinc sulfide doped with manganese, and wherein one of the layers of electrodes includes a roughened surface.

18. The electroluminescent device as set forth in claim 3, wherein the first electrode layer and the second electrode layer is formed from aluminum, the light-emitting layer is formed from zinc sulfide doped with manganese, and wherein one of the layers of electrodes includes a roughened surface.

19. The electroluminescent device as set forth in claim 1, wherein the first electrode layer is formed from indium tin oxide, the second electrode layer is a multilayer electrode formed from aluminum and lithium fluoride, and the light-emitting layer is formed from doped 8-hydroxyquinoline aluminum.

20. The electroluminescent device as set forth in claim 3, wherein the first electrode layer is formed from indium tin oxide, the second electrode layer is a multilayer electrode formed from aluminum and lithium fluoride, the light-emitting layer is formed from doped 8-hydroxyquinoline aluminum, and the crystallite is located within the inter-pixel area.

21. The electroluminescent device as set forth in claim 1 further comprising:
a first and second dielectric layers; and
a viewing surface.

22. The electroluminescent device as set forth in claim 19 further comprising a light-absorbing layer.

23. The electroluminescent device as set forth in claim 1 further comprising:
a hole injection layer;
a hole transport layer;
a electron transport layer; and
a viewing surface.

24. The electroluminescent device as set forth in claim 21 further comprising a layer of inert gas with desiccant.

25. A method of fabricating an electroluminescent device that emits light to an observer and wherein the device has a plurality of layers, the method comprising:
depositing the layers onto a viewing surface; and
thermally treating the layers such that a layer produces a crystalline scattering state.

26. The method as set forth in claim 25, wherein the crystalline scattering state is a crystallite capable of enhancing the amount of light emitted to the observer.

27. The method as set forth in claim 25, wherein laser annealing is used to thermally treat the layers.

28. The method as set forth in claim 25, wherein ultra-violet exposure is used to thermally treat the layers.

29. The method as set forth in claim 25, further comprising removing a crystalline scattering state that substantially reduces the amount of light being emitted from the device.

30. An electroluminescent device including a plurality of layers, the device comprising:
a first electrode layer of a substantially non-transparent material;
a second electrode layer of a substantially non-transparent material; and
a light-emitting layer disposed between the first and second electrode layers.

31. The electroluminescent device as set forth in claim 30, wherein the light-emitting layer includes a polycrystalline material containing at least one crystallite.

32. The electroluminescent device as set forth in claim 30, wherein the first electrode layer includes a plurality of row electrodes and the second electrode layer includes a plurality of column electrodes.

33. The electroluminescent device as set forth in claim 32, further comprising:
a crystallite;
a plurality of pixels, wherein the pixel is an area of the device where a row electrode overlaps a column electrode; and
a plurality of inter-pixel areas, wherein the inter-pixel area is an area of the device void of any electrode overlapping another electrode, and wherein the crystallite is positioned in one inter-pixel area.

34. The electroluminescent device as set forth in claim 33, wherein the crystallite scatters light emitted from the light emitting layer.

35. The electroluminescent device as set forth in claim 30, further comprising a crystallite formed in a layer, the crystallite operable to scatter light emitted from the light-emitting layer.

36. The electroluminescent device as set forth in claim 30, wherein the first electrode layer and the second electrode layer are layers formed from metal.

37. The electroluminescent device as set forth in claim 34, wherein the first electrode layer and the second electrode layer are formed from aluminum.

38. The electroluminescent device as set forth in claim 37, wherein the first electrode layer includes a roughened surface.

39. The electroluminescent device as set forth in claim 38, wherein the roughened surface is formed by laser annealing.

40. An electroluminescent device having a plurality of layers deposited on a viewing surface, the device comprising:
a light-emitting means;
a light-scattering means for increasing a luminance of the device; and
a conducting means for establishing a voltage across the light-emitting means.

41. The electroluminescent device as set forth in claim 40, wherein the light-emitting means includes the light-scatting means.

42. The electroluminescent device as set forth in claim 41, wherein the light-scattering means is at least one crystallite within the light-emitting means.

43. The electroluminescent device as set forth in claim 40, wherein the light-scattering means is a gap within a layer of the device.

44. The electroluminescent device as set forth in claim 43, where the gap includes two sidewalls positioned at an angle.

45. The electroluminescent device as set forth in claim 40, wherein the conducting means includes the light-scattering means.

46. The electroluminescent device as set forth in claim 40, wherein the light-scattering means is a roughened surface of a layer within the device.
